(19) United States
(12) Patent Application Publication
(10) Pub. No.: US 2004/0058088 A1
(43) Pub. Date: Mar. 25, 2004

(54) Processing method for forming thick film having improved adhesion to surface-modified substrate and apparatus thereof

(76) Inventors: Young-Whoan Beag, Seoul (KR); Sung Han, Seoul (KR); Jun-Sik Cho, Seoul (KR); Cheol-Su Lee, Seoul (KR); Sung-Soo Koh, Yongin-Shi (KR); Jin-Woo Seok, Seoul (KR)

Correspondence Address: BIRCH STEWART KOLASCH & BIRCH, PO BOX 747, FALLS CHURCH, VA, 22040-0747, US

(21) Appl. No.: 10/651,956

(22) Filed: Sep. 2, 2003

(30) Foreign Application Priority Data
Sep. 25, 2002 (KR) 0058265

(51) Int. Cl. C23C 14/12; C23C 14/20; H05H 1/00; C25D 5/54; C25D 5/56; C23C 28/00; C23C 14/34; C23C 14/46; C23C 14/35; C25D 17/00; C23C 16/00

(52) U.S. Cl. 427/525; 427/536; 205/158; 205/165; 205/183; 204/192.11; 204/192.15; 204/242; 204/298.04; 204/298.02; 204/298.16; 118/723 R; 118/723 EB

(57) ABSTRACT

Disclosed is a processing method for forming a thick film having an improved adhesion to a surface-modified substrate and an apparatus thereof enabling to form a thick film having the improved adhesion to a polymeric surface by modifying the polymeric surface to have a hydrophilic property. The method includes the steps of preparing a substrate of a polymer material, surface-modifying the substrate, forming a seed layer on the substrate, and forming the thick film on the seed layer. The apparatus includes an unloading area supplying a substrate of a polymer material, a surface treating area modifying a surface of the substrate, a seed layer formation area forming a seed layer on the surface-modified substrate, a thick film formation area forming a thick film on the seed layer, and a loading area loading the substrate.

### BACKGROUND OF THE INVENTION

1. Field of the Invention

The present invention relates to processing methods for forming a thick film having an improved adhesion to a surface-modified substrate and an apparatus thereof enabling to form a thick film having the improved adhesion to a polymeric surface by modifying the polymeric surface to have a hydrophilic property.

2. Background of the Related Art

Generally, a technology of forming a thin film or layer having an excellent adhesion on a polymeric surface can have various and wide applications to a production of a PCB (printed circuit board) or FPC (flexible printed circuit) substrate, EMI(electromagnetic interference) shielding, development of electronic devices, and the like. There are many methods of forming a thick film such as electroless plating, electroplating, vacuum deposition, and the like. Yet, such simple methods fail to improve adhesion between thick films and polymeric surface.

Specifically, polymers containing fluorine are very stable and show hydrophobicity. Hence, it is unable to expect a strong adhesion between such polymers and thick films.

In order to improve the adhesion to the thick film formed on the polymeric surface, many methods of modifying a surface of the polymer material by plasma, UV-rays, high-energy ion beam, etc have been tried. Yet, the surface modification effect is insufficient to limit the selective species of the polymer material used as a substrate material. And, a polymer material enabling to attain a predetermined level of the adhesive strength is limitedly used.

In order to clear the selection restrictions of the above-mentioned polymer materials and attain a sufficient effect of surface treatment, a surface modification of polymer by ‘ion assisted reaction’ (U.S. Pat. No. 5,783,641) has been developed, which is explained in brief as follows.

First of all, Ion Assisted Reaction (IAR) is a method of modifying only a surface of a polymer material in a manner that, after a vacuum chamber is evacuated to 1×10⁻⁶ Torr, an ion beam having a low energy below 5.0 KeV is irradiated onto a surface of a polymer material in a reactive gas ambience of 1×10⁻⁵˜1×10⁻² Torr by controlling a flow rate of a reactive gas.

Hence, Ion Assisted Reaction hardly causes damage on the surface of the polymer material due to the ion beam irradiation, maintains the inherent properties of the polymer material, and enables to endow the surface with new functions. The low-energy ion beam irradiation forms radicals on the surface of the polymer material, whereby the activated surface brings about a chemical reaction with the reactive gas to generate new polar functional groups. As a result, a surface energy of the polymer material gets close to that, 72 erg/cm2, of water. Thus, the surface of the polymer material shows a strong adhesive strength to other materials as well as the increased hydrophilic property.

The ion assisted reaction method disclosed in U.S. Pat. No. 5,783,641 enables to attain the improvement of the adhesive strength effectively if the surface of the polymer material is free from a thermal damage in a following process of forming a thin layer. Yet, if a cooling of the vacuum chamber is not easy or the polymer material is very sensitive to thermal damage, or if high-power deposition generating a high temperature inside the vacuum chamber is carried out to increase a productivity of thick film formation by increasing a deposition rate, the thermal damage on the surface of the polymer material due to the high temperature reduces the surface treatment effect and finally brings about detachment of the thick film.

For instance, when high power is supplied to increase a deposition rate in Magnetron Sputtering widely used as a method of forming a thick film, plasma of high density is formed to worsen the thermal damage of the surface of the polymer material in the high-density plasma. Hence, the surface treatment effect is remarkably reduced.

In Magnetron Sputtering, an inert gas such as Ar and the like is generally injected into a vacuum chamber up to 1×10⁻³˜1×10⁻² Torr, and a voltage is applied between an anode and a cathode corresponding to a target. Then, electrons existing in vacuum are accelerated to collide with gas atoms. As a result, the gas atom loses its electron(s) to be ionized and forms the plasma of the gas. In this case, if a magnet is arranged at the cathode, the electron does a revolution movement near the target surface and is restrained near the target surface to form an ion. Namely, a generation efficiency of plasma increases.

The cathode corresponding to the target has a relatively negative potential, whereby the energetic and positively charged particles generated with a high efficiency in plasma are accelerated to collide with the target surface to eject a target material, which is called ‘sputtering’. Hence, the sputtered particles are attached to the surface of the polymer material to accomplish ‘deposition’.

In this case, a sputtering efficiency, i.e. a deposition rate, is proportional to power consumption. Hence, if high power is supplied to increase the deposition rate, a high temperature is generated by the generation of the high-density plasma.

Conventional method of forming the thick film and apparatus thereof according to the related art has the following disadvantages or problems.

First of all, the simple method for forming the thick film on the polymer material by electroless plating, electroplating, or vacuum deposition fails to improve the adhesive strength between the polymer surface and the film. If vacuum deposition of high power is carried out after surface treatment of polymer surface modification by Ion Assisted Reaction, the surface treatment effect is reduced by thermal damage resulting in detachment of the thick film.

### SUMMARY OF THE INVENTION

Accordingly, the present invention is directed to a processing method for forming a thick film having an improved adhesive strength to a surface-modified substrate and an apparatus thereof that substantially obviates one or more problems due to limitations and disadvantages of the related art.

An object of the present invention is to provide a processing method for forming a thick film and an apparatus thereof enabling to form the thick film having an improved adhesive strength to a polymer material by increasing a surface energy to modify a surface of the polymer material for excellent adhesion and by forming a seed layer.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a processing method of forming a thick film having an improved adhesive strength according to the present invention includes the steps of preparing a substrate of a polymer material, surface-modifying the substrate, forming a seed layer on the substrate, and forming the thick film on the seed layer.

In another aspect of the present invention, an apparatus for forming a thick film having an improved adhesive strength includes an unloading area supplying a substrate of a polymer material, a surface treating area modifying a surface of the substrate, a seed layer formation area forming a seed layer on the surface-modified substrate, a thick film formation area forming a thick film on the seed layer, and a loading area loading the substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a schematic diagram of an apparatus for forming a thick film having an improved adhesive strength to a substrate according to the present invention;

FIG. 2 illustrates a diagram of a test result for surface treatment of a silicon rubber substrate;

FIG. 3A and FIG. 3B illustrate diagrams of a test result for surface treatment of a PC substrate;

FIG. 4 illustrates a diagram of a Teflon substrate having a thick film formed thereon;

FIG. 5 illustrates a diagram of a Teflon substrate having a seed layer and a thick film formed thereon; and

FIG. 6A and FIG. 6B illustrate diagrams of test results of a PC substrate having a thick film formed thereon.

### DETAILED DESCRIPTION OF THE PREFERRED EMBODIMENTS

Reference will now be made in detail to the preferred embodiments of the present invention, examples of which are illustrated in the accompanying drawings.

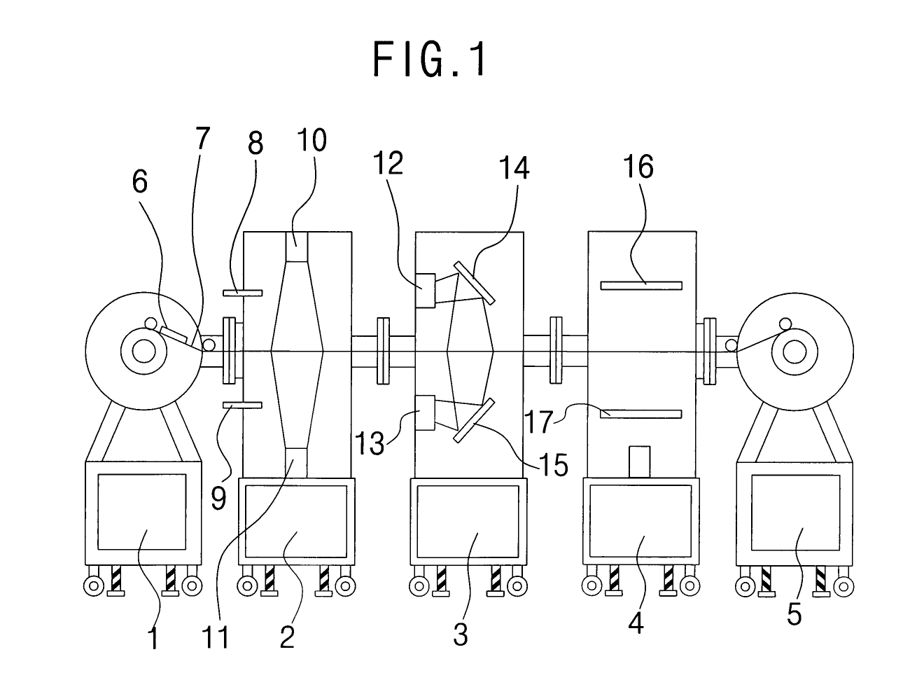

FIG. 1 illustrates a schematic diagram of an apparatus for forming a thick film having an improved adhesive strength to a substrate according to the present invention.

Referring to FIG. 1, a vacuum chamber of an apparatus for forming a thick film includes five areas. The vacuum chamber includes an unloading area 1 supplying a substrate 6 to form a thick film, a surface treatment area 2 modifying a surface of the substrate 6 made of a polymer material, a seed layer formation area 3 forming a seed layer on the surface-treated substrate 6, a thick film formation area 4 forming a thick film on the substrate 6 having the seed layer formed thereon, and a loading area 5 loading the substrate 6 having the thick film formed thereon. And, in order to prevent the substrate from hanging down due to a weight of the substrate as a treatment length increases, tension controlling rolls (not shown in the drawing) are properly installed at connecting parts among the surface treatment, seed layer formation, and thick film formation areas 2, 3, and 4, respectively.

The unloading and loading areas 1 and 5 wind or unwind a conveyer 7 transferring the substrate 6 made of the polymer material to the surface treatment, seed layer formation, and thick film formation areas 2, 3, and 4 or control a tension.

The surface treatment area 2 modifying the surface of the substrate 6 made of the polymer material includes first and second gas supply inlets 8 and 9 supplying a reactive gas inside and first and second surface treatment ion sources 10 and 11 including an ionization unit ionizing an inert or reactive gas supplied to each ion sources and an acceleration unit accelerating the ionized gas ions to extract as ions.

And, ion beams below 2.5 KeV, which are generated from the first and second surface treatment ion sources 10 and 11, respectively, activate the surface of the substrate 6 made of the polymer material without any surface damage. The activated surface of the substrate 6 chemically reacts with the entering reactive gas to form new polar functional groups on the surface of the substrate 6. Hence, the surface becomes hydrophilic to contribute an improvement of an adhesive strength to another material.

The substrate 6 made of the polymer material is the polymer material containing carbon and hydrogen and selected from the group consisting of PE, PP, PS, etc., the polymer material containing carbon, hydrogen, and oxygen and selected from the group consisting of polyesters, polycarbonates, polyethers, PC, PET, PMMA, etc., the polymer material containing carbon, hydrogen, oxygen, and nitrogen and selected from the group consisting of polyamines, polyimides, polyurethanes, PA, PI, PU, etc., the polymer material containing carbon, hydrogen, and nitrogen and selected from the group consisting of polyimines, phenol-and-amine-formaldehydes (polyethylene imine), etc., the polymer material containing carbon, hydrogen, oxygen, and sulfur and selected from the group consisting of polyester sulfone (polysulfones), PES, etc., the polymer material containing carbon, hydrogen, and fluorine and selected from the group consisting of polyvinylidene fluoride (PVDF), etc., the polymer material containing carbon and fluorine and selected from the group consisting of PTFE, Teflon, etc., the polymer material containing carbon, hydrogen, and chlorine and selected from the group consisting of polyvinyl chloride, polyvinylidene chloride (PVC), etc., or the polymer material containing carbon, hydrogen, oxygen, and silicon and selected from the group consisting of polydimethylsiloxane, polycarbonate-siloxanes (silicon rubber), etc.

For a process condition for modifying the surface of the substrate 6, an acceleration voltage is 50 eV˜5.0 KeV, an ion dose is 1×10¹⁴˜5×10¹⁸ ions/cm², a flow rate of the reactive gas is 0˜1,000 ml/min, and a working pressure is 1×10⁻⁵˜1×10⁻² Torr.

And, any ion sources enabling to control an ion energy and the number of ions precisely such as Kaufman, Cold Hollow Cathode, Electron Cyclotron Resonance, Radio Frequency types, etc can be used as the ion source for the surface modification of the substrate 6.

The seed layer formation area 3 forming the seed layer on the surface-modified substrate 6 is constituted with first and second sputter deposition ion sources 12 and 13 including an ionization unit ionizing an inert or reaction gas supplied to a ion source and an acceleration unit accelerating an ionized gas ion to extract as an ion and first and second sputter targets 14 and 15 providing seed layer formation materials, respectively.

The ion sources are the ECR (electron cyclotron resonance) type using 2.45 GHz microwave discharge, and each of the ion sources is constituted with three combined modules of 200 mm to handle a wide width of a total length of 600 mmm. A maximum acceleration energy is 2 KeV, a current density is over 2 mA/cm², and a uniform zone within ±5% is over 400 mm.

As shown in the seed layer formation area 3, the energetic ion beams from the first and second sputter deposition ion sources 12 and 13 are irradiated onto the first and second sputter targets 14 and 15, respectively. Atoms of the first and second sputter targets 14 and 15 which get energy by the collisions with the incident ions are ejected from the first and second sputter targets 14 and 15 to become sputter particles.

The sputter particles arrive on a surface of the polymer material to form a film thereon, thereby enabling to improve an adhesive strength, densification, uniformity, crystallinity of the film, and the like. Such a method is called an ion beam sputtering method. The ion beam sputtering method enables to form a layer at the room temperature and is suitable for a low temperature process. And, the ion beam sputtering method is a very effective method of forming a layer on a polymer material vulnerable to thermal damage.

In forming a seed layer, there are various methods such as Low Power Evaporation causing no thermal damage on a substrate, Thermal Evaporation causing no thermal damage on a polymer substrate, E-beam Evaporation, RF Sputtering, DC Magnetron Sputtering, etc. as well as Ion Beam Sputtering.

The thick film formation area 4 forming a thick film on the seed layer includes first and second cathode targets 16 and 17 for RF(radio frequency), DC (direct current) or RF magnetron, MF magnetron, single magnetron, or dual magnetron sputtering.

Such methods are properly selected in accordance with the species of the base material of the film such as insulator, oxide, or conductor or the required characteristics of the resulting thick film.

FIG. 1 shows the apparatus for forming a thick film on a roll type polymer material. In case products which have difficulty in processing with roll type, the unloading and loading areas 1 and 5 can be modified into a batch or in-line type apparatus, which enables to process a single face or both faces if necessary.

Moreover, a thick film can be formed by electroless plating right after the surface of the substrate 6 made of the polymer material has been treated in the surface treatment area 2. In another way, the substrate 6 is surface-treated, the seed layer is formed, and then the thick film is formed on the seed layer by electroplating.

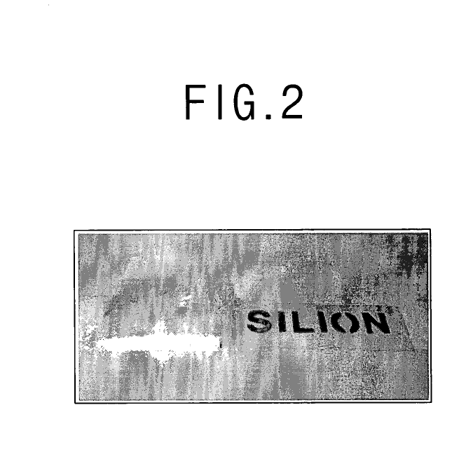

FIG. 2 illustrates a diagram of a test result for surface treatment of a silicon rubber substrate.

Referring to FIG. 2, in order to check an effect of the surface treatment, a silicon rubber substrate is surface-treated through a mask to mark characters of ‘S I L I C O N’thereon only, a Cu seed layer is deposited about 2,000 Å thick thereon, and an adhesive strength thereof is checked by a scotch tape test. It can be seen that an excellent adhesive strength is realized between the Cu seed layer and the silicon rubber substrate having a low surface energy below 30 ergs/cm².

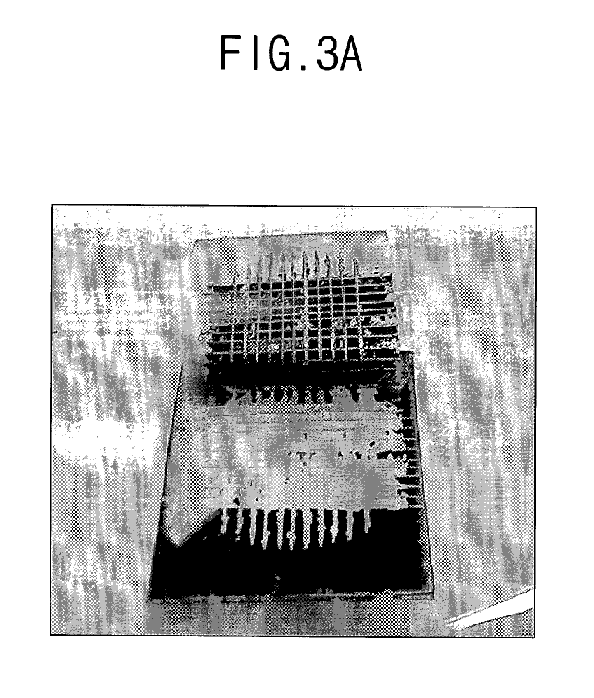

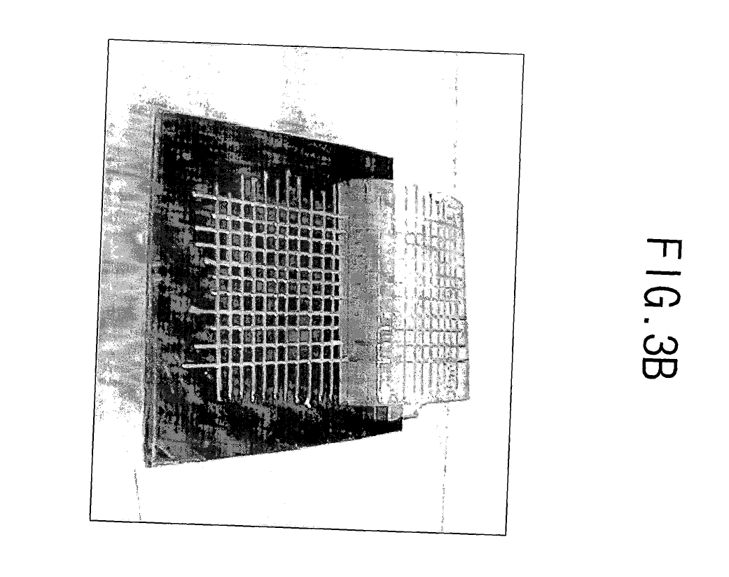

FIG. 3A and FIG. 3B illustrate diagrams of a test result for surface treatment of a PC substrate.

In order to confirm an effect of the surface treatment, a PC (polycarbonate) substrates are used as substrates, Cu seed layers are deposited about 2,000 Å thick on the not-surface-treated PC substrate and the surface-treated PC substrate, respectively, and each adhesive strength thereof is checked by a 1 mm interval cross-cut scotch tape test ASTM D3359.

Referring to FIG. 3A, a Cu seed layer is deposited about 2,000 Å thick on a PC substrate without surface-treatment on a polymer material by Ion Assisted Reaction. And, an adhesive strength thereof is checked by a 1 mm interval cross-cut scotch tape test ASTM D3359. The PC substrate is used as a substrate and the Cu seed layer is deposited on the PC substrate, in which the adhesive strength between the PC substrate and the Cu seed layer is so poor that an detachment occurs.

Referring to FIG. 3B, a Cu seed layer is deposited about 2,000 Å thick on a PC substrate surface-treated with a polymer material by Ion Assisted Reaction. And, an adhesive strength thereof is checked by a 1 mm interval cross-cut scotch tape test ASTM D3359. The PC substrate is used as a substrate and the Cu seed layer is deposited on the surface-treated PC substrate, in which the adhesive strength between the PC substrate and the Cu seed layer is excellent.

The excellent adhesive strength between the PC substrate and the thin film (Cu seed layer) is realized. Yet, the thickness of 2,000 Å of the Cu seed layer is not enough to be used as a material of a FPC substrate, a PCB substrate, and the like or fails to provide a sufficient EMI shielding effect. Hence, a thick film formation process should be added thereto. Electroless plating which has a fast deposition rate is used as a method of forming a thick film on an insulating polymer substrate.

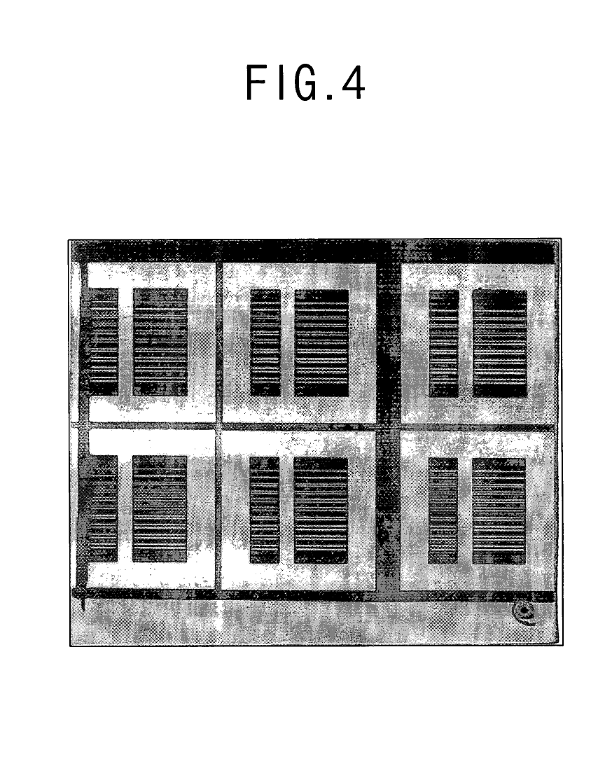

FIG. 4 illustrates a diagram of a Teflon substrate having a thick film formed thereon.

Referring to FIG. 4, a Teflon substrate is surface-treated by a surface treatment method of a polymer material by Ion Assisted Reaction and a Cu layer of 1 μm thickness is then formed by electroless plating, whereby a PCB substrate having an excellent adhesive strength can be provided. Yet, electroless plating is a method of forming a layer by dipping a Teflon substrate in an electrolyte containing a predetermined amount of a layer-forming material therein. If the layer-forming material in the electrolyte is completely consumed, it is unable to form a layer anymore. Hence, there is a limitation in attaining a required thickness of the thick film. Therefore, it is unable to provide various applications of the thick film since it is difficult to attain the thickness of the thick film over 1 μm thick.

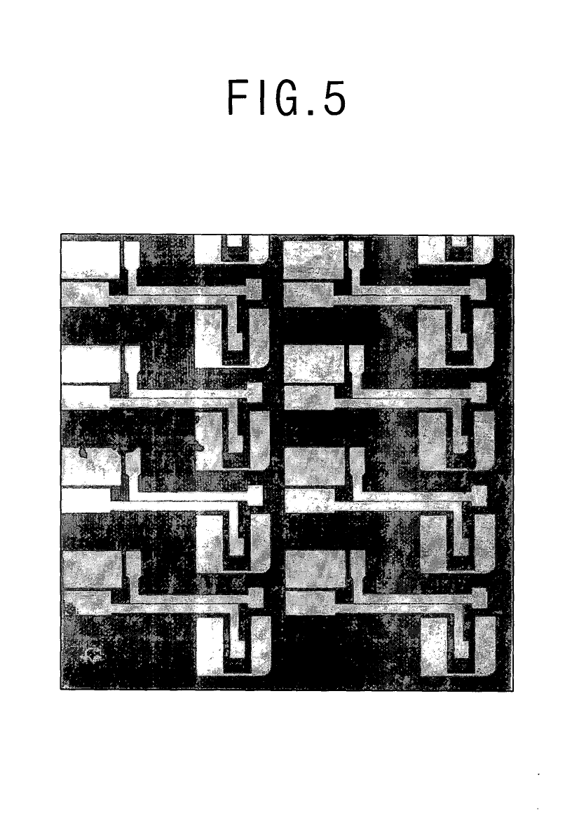

FIG. 5 illustrates a diagram of a Teflon substrate having a seed layer and a thick film formed thereon.

Referring to FIG. 5, a Teflon substrate is surface-treated by a surface treatment method of a polymer material by Ion Assisted Reaction, an conducting seed layer having an excellent adhesive strength to a substrate is formed by low temperature deposition of low power free from causing thermal damage on the polymer substrate as a second process, and a Cu layer of 4˜5 μm thickness is formed thereon by electroplating having a fast deposition rate. The adhesive strength between the seed layer and a layer made by electroplating is excellent as well as that between the Teflon substrate and the seed layer.

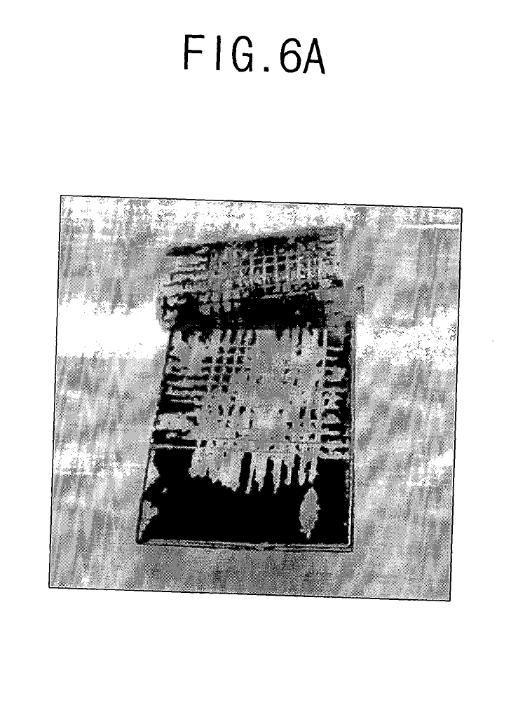

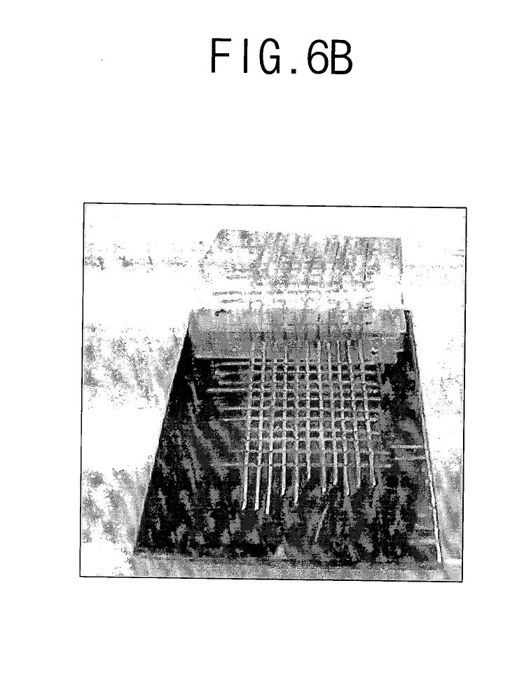

FIG. 6A and FIG. 6B illustrate diagrams of test results of a PC substrate having a thick film formed thereon.

A PC substrate is surface-treated, a thick film is formed thereon, and a cross-cut scotch tape test ASTM D3359 is carried thereon. And, the corresponding results are shown in FIG. 6A and FIG. 6B, respectively.

Referring to FIG. 6A, a PC substrate is surface-treated by a surface treatment method of a polymer material by Ion Assisted Reaction, a thick film is formed thereon by high power PVD(physical vapor deposition) having a high deposition rate, and an adhesive strength between the PC substrate and the thick film is then checked by a 1 mm interval cross-cut scotch tape test ASTM D3359. The result indicates that a thick film is detached from the substrate since a surface treatment effect is reduced by thermal damage due to high power.

Referring to FIG. 6B, a PC substrate is surface-treated by a surface treatment method of a polymer material by Ion Assisted Reaction, a conducting seed layer having an excellent adhesive strength to the substrate is formed about 2,000 Å thick thereon by low temperature deposition free from causing thermal damage on the polymer substrate as a second process, a thick film is formed by high power PVD having a fast deposition rate, and an adhesive strength between the PC substrate and the thick film is then checked by a 1 mm interval cross-cut scotch tape test ASTM D3359. The result indicates that the thick film has an excellent adhesive strength since the seed layer having the excellent adhesive strength protects the surface-treated substrate from high power plasma of high temperature.

Accordingly, a processing method for forming a thick film having an improved adhesive strength to a surface-modified substrate and an apparatus thereof according to the present invention has the following effects or advantages.

First of all, in the related art, before the thick film is formed on the polymer material, surface treatment is carried out by a method of treating a surface of the polymer by plasma, UV (ultraviolet) rays, ion beam, or the like to improve the adhesive strength between the surface of the polymer material and the thick film or polymer surface modification by Ion Assisted Reaction for a sample, which is sensitive to thermal damage or has difficulty in cooling. Then, high power vacuum deposition or the like is tried thereon to increase a productivity of the thick film formation by increasing a deposition rate. Yet, such a surface treatment method has a poor effect or a surface of the polymer is damaged in the process of forming the thick film. Hence, the adhesive strength is reduced as well as the surface treatment effect due to the thermal damage, whereby the detachment of the thick film is brought about.

Therefore, in order to overcome such a problem or disadvantage, the present invention forms the seed layer after the surface of the polymer has been modified, thereby enabling to form the thick film having the excellent adhesive strength to the substrate.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A processing method of forming a thick film having an improved adhesive strength, comprising the steps of:
preparing a substrate of a polymer material;
surface-modifying the substrate;
forming a seed layer on the substrate; and
forming the thick film on the seed layer.

2. The processing method of claim 1, wherein the substrate is made of the polymer material containing carbon and hydrogen and selected from the group consisting of PE, PP, PS, etc.

3. The processing method of claim 1, wherein the substrate is made of the polymer material containing carbon, hydrogen, and oxygen selected from the group consisting of polyesters, polycarbonates, polyethers, PC, PET, PMMA, etc.

4. The processing method of claim 1, wherein the substrate is made of the polymer material containing carbon, hydrogen, oxygen, and nitrogen selected from the group consisting of polyamines, polyimides, polyurethanes, PA, PI, PU, etc.

5. The processing method of claim 1, wherein the substrate is made of the polymer material containing carbon, hydrogen, and nitrogen selected from the group consisting of polyimines, phenol-and-amine-formaldehydes (polyethylene imine), etc.

6. The processing method of claim 1, wherein the substrate is made of the polymer material containing carbon, hydrogen, oxygen, and sulfur selected from the group consisting of polyester sulfone (polysulfones), PES, etc.

7. The processing method of claim 1, wherein the substrate is made of the polymer material containing carbon, hydrogen, and fluorine selected from the group consisting of polyvinylidene fluoride (PVDF), etc.

8. The processing method of claim 1, wherein the substrate is made of the polymer material containing carbon and fluorine selected from the group consisting of PTFE, Teflon, etc.

9. The processing method of claim 1, wherein the substrate is made of the polymer material containing carbon, hydrogen, and chlorine selected from the group consisting of polyvinyl chloride, polyvinylidene chloride (PVC), etc.

10. The processing method of claim 1, wherein the substrate is made of the polymer material containing carbon, hydrogen, oxygen, and silicon selected from the group consisting of polydimethylsiloxane, polycarbonate-siloxanes (silicon rubber), etc.

11. The processing method of claim 1, wherein the substrate is surface-modified by an acceleration voltage of 50 eV˜5.0 KeV, an ion dose of 1×10¹⁴˜5×10¹⁸ ions/cm², a reactive gas flow rate of 0˜1,000 ml/min, and a working pressure of 1×10⁻⁵˜1×10⁻² Torr.

12. The processing method of claim 1, wherein an ion source generating energetic particles used for surface modifying the substrate is selected from the group consisting of Kaufman, Cold Hollow Cathode, Electron Cyclotron Resonance, and Radio Frequency types.

13. The processing method of claim 1, wherein the seed layer is deposited at a deposition rate of maximum 20 Å/sec using an ion source of an electron cyclotron resonance (ECR) type for ion beam sputter.

14. The processing method of claim 13, wherein the ion source is the ECR (electron cyclotron resonance) type using 2.45 GHz microwave discharge, comprises three combined modules of 200 mm to handle a wide width of a total length of 600 mmm, and has a maximum acceleration energy of 2 KeV, a current density over 2 mA/cm², and a uniform zone within ±5% over 400 mm.

15. The processing method of claim 1, wherein the seed layer is formed by a method selected from the group consisting of ion beam sputtering, low power thermal evaporation, E-beam Evaporation, RF Sputtering, and DC Magnetron Sputtering.

16. The processing method of claim 1, wherein the thick film is formed by a method selected from the group consisting of physical vapor deposition (PVD), electroplating, and electroless plating.

17. An apparatus for forming a thick film having an improved adhesive strength, comprising:
an unloading area supplying a substrate of a polymer material;
a surface treating area modifying a surface of the substrate;
a seed layer formation area forming a seed layer on the surface-modified substrate;
a thick film formation area forming a thick film on the seed layer; and
a loading area loading the substrate.

18. The apparatus of claim 17, further comprising a conveyer transferring the substrate from the unloading area to the loading area through the surface treatment, seed layer formation, and thick film formation areas, the conveyer winding or unwinding the substrate, and the conveyer controlling a tension thereof.

19. The apparatus of claim 17, the surface treatment area comprising:
a gas supply inlet supplying a first reactive gas inside;
an ionization unit ionizing an inert or second reactive gas supplied to an ion source separately; and
an acceleration unit accelerating the ionized inert or second reactive gas ion to extract as an ionized species.

20. The apparatus of claim 17, the seed layer formation area comprising:
an ion source including an ionization unit ionizing an inert or second reactive gas supplied to a sputter deposition ion source separately and an acceleration unit accelerating the ionized inert or second reactive gas ion to extract as an ionized species; and
a sputter target providing a source of the seed layer.

21. The apparatus of claim 17, wherein the thick film formation area forms the thick film on the seed layer using one of cathode targets for RF(radio frequency), DC (direct current) or RF magnetron, MF magnetron, single magnetron, and dual magnetron sputterings.

22. The apparatus of claim 17, wherein a type of the apparatus is selected from the group consisting of roll, batch, and in-line types in accordance with a method of processing the substrate.
